(19) United States
(12) Patent Application Publication
(10) Pub. No.: US 2023/0188122 A1
(43) Pub. Date: Jun. 15, 2023

(54) PULSE WIDTH MODULATED CMOS SUB-HERTZ TIMER

(71) Applicant: King Fahd University of Petroleum and Minerals, Dhahran (SA)

(72) Inventors: Hussain Abdullah Alzaher, Dhahran (SA); Hamza Shahid, Dhahran (SA)

(73) Assignee: King Fahd University of Petroleum and Minerals, Dhahran (SA)

(21) Appl. No.: 16/515,309

(22) Filed: Jul. 18, 2019

(51) Int. Cl. H03K 3/3565; G06F 1/26

(52) U.S. Cl. CPC H03K 3/3565; G06F 1/26; H03K 7/08

(57) ABSTRACT

A low voltage single supply, ultra-low power sub hertz timer using a CMOS Schmitt trigger operating in sub-threshold region is presented. Sub-Hertz operation is achieved by controlling the amount of current for charging and discharging a capacitor at the control input of the Schmitt rather than by using large passive components. Pulse width modulation is achieved choosing the width per unit length parameters of transistors used in charging and discharging control blocks for the capacitor. The circuit uses a low supply voltage and can be designed for the higher voltages if required by specific applications. The circuit can produce sub-hertz oscillation with pulse width modulation. The capacitor has a small footprint compatible with integrated circuits. Power consumption is small with short ON times.

### STATEMENT OF ACKNOWLEDGEMENT

The author would like to acknowledge the financial support provided by the King Abdullah University of Science and Technology-King Fahd University of Petroleum and Minerals (KAUST-KFUPM) Intuitive Program, Riyadh, Saudi Arabia through research grant 001.

### BACKGROUND

### Technical Field

The present disclosure is directed to a pulse width modulated CMOS sub-hertz timer.

### Description of the Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

With advancements in engineering and technology, timers play an important role in the operation of different blocks of integrated circuits used in biomedical, industrial, and environmental monitoring applications. A wide variety of target applications for sub-hertz timers are found in the biomedical field for use in periodic monitoring of health-related parameters in wearable and implantable devices. In industry, a sub-hertz timer is used as a wake-up timer for chemical and gas monitoring sensors. Many applications are found in battery operated devices.

In order to reduce power consumption, a block may be operated in a pulsed manner instead of continuously. In particular, a sub-hertz timer may be used in biomedical applications, such as monitoring of eye pressure or filters for breathing monitoring system. (See Rodriguez-Villegas, E.; Casson, A.; Corbishley, P.: A sub-Hertz nanopower low pass filter. IEEE Transactions on Circuits and Systems II. 58(2), pp. 351-355 (2011); Phillip, N.; Arun, P.; Anantha, C.: Ultra Low-Energy Relaxation Oscillator With 230 fJ/cycle. IEEE Journal of Solid-State Circuits. 51(4), pp. 789-799 (2016); and Rafiq Dar, M; Kant, N.; Khanday, F.; Psychalinos, C.: Fractional-Order Filter Design for Ultra-Low Frequency Applications. In: IEEE International Conference on Recent Trends in Electronics Information Communication Technology, pp. 20-21 (2016), each incorporated herein by reference in their entirety).

The timer may also be used in the design of wireless gas sensors. (See Zhang, Y.; Rhee, W.; Kim, T.; Park, H.; Wang, Z.: A 0.35-0.5-V 18-152 MHz Digitally Controlled Relaxation Oscillator with Adaptive Threshold Calibration in 65-nm CMOS. IEEE Transactions on Circuits and Systems-II. 62(8), pp. 736-740 (2015); Aita, A.; De la Cruz, J.; Bashirullah R.: A 0.45V CMOS relaxation oscillator with ±2.5% frequency stability from −55° C. to 125° C. In: IEEE International Symposium on Circuits and Systems. pp. 493-496 (2015); Srivyshnavi, T.; Srinivasulu, A.: A current mode Schmitt trigger using Current Differencing Transconductance Amplifier. In: IEEE International Conference on Signal Processing, Communication and Networking, (2015); Yuan, F.: A high-speed differential CMOS Schmitt trigger with regenerative current feedback and adjustable hysteresis. Analog Integrated Circuits and Signal Processing. 63(1), pp. 121-127 (2010); Ni, Y.; Onabajo, M.: A low-power temperature-compensated CMOS relaxation oscillator. Analog Integrated Circuits and Signal Processing. 79(2), pp. 309-317 (2014); and Xu, Z.; et al.: A Supply Voltage and Temperature Variation-Tolerant Relaxation Oscillator for Biomedical Systems Based on Dynamic Threshold and Switched Resistors. IEEE Transactions on Very Large-Scale Integration Systems. 23(4), pp. 786-790 (2015), each incorporated herein by reference in its entirety).

Further, power consumption is one of the most significant factors in the efficiency of battery operated and implantable devices. (See Seon, Y.; et al.: Impact on Off-state Leakage Current in PMOS Device by Metallic Contamination. In: IEEE International Symposium on Semiconductor Manufacturing, pp. 179-182 (2006), incorporated herein by reference in its entirety).

A sub-hertz oscillator was investigated for leakage current phenomena. (See Zhai, B.; et al.: A 2.60 pJ/Inst Subthreshold Sensor Processor for Optimal Energy Efficiency. In: Symposium on VLSI Circuits, Digest of Technical Papers, (2006), incorporated herein by reference in its entirety). Special thin oxide transistors were used as current sources and a thick gate oxide transistor was used as a capacitor. However, such transistors are not generic and often unavailable in standard CMOS technologies.

Timers for such systems have very low power requirements. Typically, the power consumption of these timers when in idle state are much less than the rest of the system and hence lead to significantly more power efficient solutions. One solution is to use crystal oscillators, but these are hard to integrate and are not standard components in integrated circuits (ICs). Further, crystal oscillators have high power consumption due to their larger area as compared to the entire circuit.

In sub-hertz timers, leakage current results in lower power consumption, but reduces circuit reliability. A further concern with sub-hertz timers is that leakage current can vary with the operating conditions of transistor. This leakage current can cause metallic contamination of the transistor, which will decrease the performance of the timer over time. (See McCorquodale, M. et al.: A 0.5-to-480 MHz Self-Referenced CMOS Clock Generator with 90 ppm Total Frequency Error and Spread-Spectrum Capability. In: IEEE International Solid-State Circuits Conference, pp. 349-351 (2008), incorporated herein by reference in its entirety).

A Schmitt trigger, commonly used in timers, has two threshold voltages, Vₜ₁ and Vₜ₂, that determine its switching triggers. (See Lin, Y-S.; Sylvester, D.; Blaauw, D: A sub-pW timer using gate leakage for ultra-low-power sub-Hz monitoring systems. In: IEEE Custom Intergrated Circuits Conference, pp. 397-400 (2007), incorporated herein by reference in its entirety).

It is one object of the present disclosure to describe a sub-hertz timer combining sub threshold operation and current steering which overcomes the problem of metallic contamination by controlling leakage current. Other objectives include incorporating Pulse width modulation (PWM) to adapt the timer to a wide range of applications. In some aspects, the timer is based on the inverter-based Schmitt trigger and includes an inverter stage for positive feedback. Charging and discharging blocks are used to control the current through the charging and discharging path of the capacitor.

### SUMMARY

In an exemplary embodiment, a pulse width modulated sub-Hertz timer is described which includes a Schmitt trigger, and inverter block connected to the output of the Schmitt trigger, a charging control block and an discharging control block connected to the output of the inverter and further connected to a capacitor. The capacitor is connected to the input of the Schmitt trigger. The Schmitt trigger has voltage thresholds, Vₜ₁ and Vₜ₂, which switch polarity of the voltage based on the amplitude of the voltage input to the Schmitt trigger.

The voltage thresholds are adjusted by selecting design parameters of PMOS and NMOS transistors of the Schmitt trigger. The ON time and OFF time of the timer is adjusted by changing the width per unit length of transistors in the charging and discharging control blocks.

In another exemplary embodiment, a method for using a pulse width modulated sub-Hertz timer includes charging a capacitor, inputting the capacitor voltage to a Schmitt trigger of the timer, generating a first output voltage of the Schmitt trigger based on the amplitude of the input voltage, switching polarity of the output voltage when the amplitude increases above a first threshold or decreases below a second threshold, inverting the first output voltage to for a second output voltage, providing the second output voltage to the control gates of a charging control block and a discharging control block; wherein the capacitor is alternately charged by the charging control block and discharged by the discharging control block, based on the polarity of the second voltage output.

In another exemplary embodiment, a method for making a pulse width modulated sub-Hertz timer is described. The method for making includes constructing a Schmitt trigger having a first input and a first output, constructing an inverter block connected at its input to the first output, the inverter block having a second output; constructing a charging control block connected to the second output, the charging control block having a third output; constructing a discharging control block connected to the second output; the discharging control block having a fourth output; coupling a positive contact of a capacitor to the third and fourth outputs, and connecting a negative contact of the capacitor to ground and connecting the first input of the Schmitt trigger to the positive contact of the capacitor. The method for making the pulse width modulated sub-Hertz timer includes choosing the design parameters of PMOS and NMOS transistors used as switching components to adjust the ON time and OFF time of the timer and the first and second switching thresholds of the Schmitt trigger.

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A is a block diagram of the timer, according to certain embodiments.

FIG. 1B is an illustration of the source, drain and gate convention used with the PMOS and NMOS transistors of the timer.

FIG. 2 is a schematic diagram of the timer circuit, according to certain embodiments.

FIG. 3 is a design layout of the timer circuit, according to certain embodiments.

FIG. 4 is a graph of output voltage vs time for an OFF time of 44 seconds and an ON time of 2 seconds, according to certain embodiments.

FIG. 5 is a graph of output voltage vs time for an OFF time of 37 seconds and an ON time of 1 second, according to certain embodiments.

FIG. 6 is a graph of output voltage vs time for a timer having frequency of oscillation of 0.05 Hz, according to certain embodiments.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise. The drawings are generally drawn to scale unless specified otherwise or illustrating schematic structures or flowcharts.

Furthermore, the terms “approximately,” “approximate,” “about,” and similar terms generally refer to ranges that include the identified value within a margin of 20%, 10%, or preferably 5%, and any values therebetween.

Aspects of this disclosure are directed to a pulse width modulated CMOS sub-Hertz timer and method for using a pulse width modulated CMOS sub-Hertz timer.

The sub-Hertz timer of the present disclosure uses a circuit including Schmitt trigger.

A Schmitt trigger is a comparator circuit with hysteresis implemented by applying positive feedback to the noninverting input of a comparator or differential amplifier. It is an active circuit which converts an analog input signal to a digital output signal. The circuit is named a “trigger” because the output retains its value until the input changes sufficiently to trigger a change. In the non-inverting configuration, when the input is higher than a chosen threshold, the output is high. When the input is below a different (lower) chosen threshold the output is low, and when the input is between the two levels the output retains its value. The output of the Schmitt trigger is a square wave. The Schmitt trigger removes noise from the input signal.

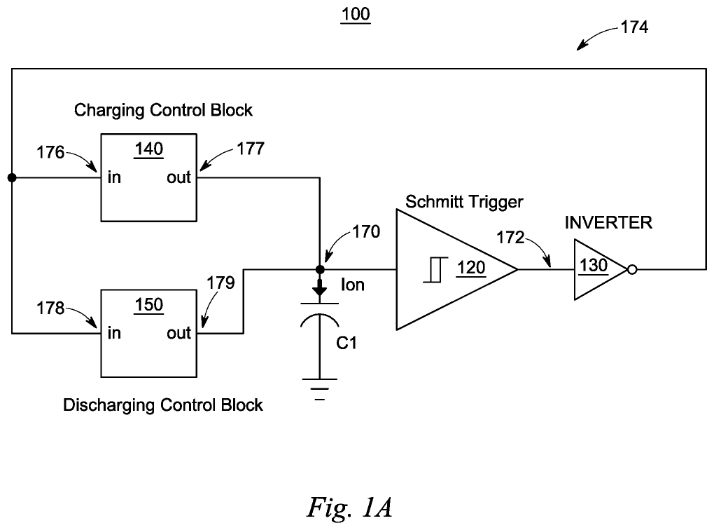

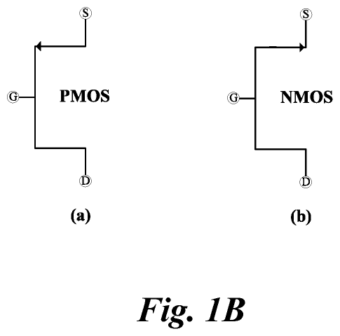

FIG. 1A shows a block diagram of the pulse width modulated CMOS sub-Hertz timer. The timer comprises a Schmitt trigger 120 connected to an inverter 130. The Schmitt trigger has threshold voltages Vₜ₁ and Vₜ₂ that determine its switching triggers. When the input voltage goes above Vₜ₁ or goes below Vₜ₂, the Schmitt trigger 120 generates an output which is inverted at inverter 130. The output from the inverter is fed back to charging block 140 or discharging block 150, depending upon the feedback signal from inverter, and provides positive feedback at the Schmitt trigger input. The inverter output is a square wave, which alternately turns the charging and discharging blocks on and off.

In a conventional Schmitt trigger oscillator, a comparator has two bias voltages which determine the amplitude of the output whenever the signal goes above or below the bias voltages. Current sources supply the current to charge and discharge a capacitor. When the charging and discharging currents are equal, the oscillation frequency of the timer is given by:

$${f}_{o s c} = \frac{2 {I}_{o n}}{C 1 ( V t 1 - V t 2 )} , \qquad ( 1 )$$

where Iₒₙ is the current for charging and discharging and Vₜ₁ and Vₜ₂ are thresholds of Schmitt Trigger. The relationship is power supply independent (See Lin, Y-S.; Sylvester, D.; Blaauw, D: A 150 pW Program-and-Hold Timer for Ultra-Low Power Sensor Platforms. In: IEEE International Solid-State Circuits Conference, Digest of Technical Papers, pp. 326-328 (2009), incorporated herein by reference in its entirety).

To attain low frequency, either a large capacitor in orders of μF must be used or the amount of current used to charge and discharge the capacitor must be small. Large capacitors have greater power consumption and are not suitable for integrated circuits with small footprints, therefore the current must be controlled to yield a large time constant (and thus a low frequency). In a non-limiting example, the value of capacitor is selected to be 100 pF (limited by available area in the chip allocated for the timer) which will yield a time period to be 46 seconds.

Pulse width modulation is required in monitoring devices as a sensor must be off, or sleep, for a long time period and on for a short time to save power. The control blocks in the charging (block 140) and discharging (block 150) paths allow control of the charging and discharging times independently of one another by controlling the path of the current flowing in or out of capacitor.

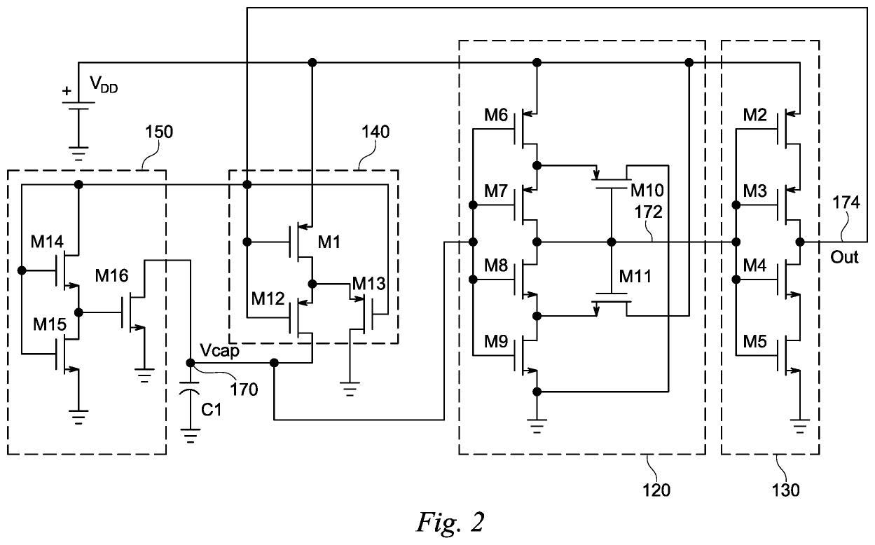

The timer circuit is shown in more detail in FIG. 2. Transistors M₆-M₁₁ constitute the cascade architecture of the CMOS Schmitt Trigger which receives the capacitor charging and discharging waveform as input. Transistors M₂-M₅ are an inverter which converts the output, Vₒᵤₜ, to the same phase as input, V_{cap}, in order to give positive feedback, 174. All transistors are in the subthreshold region to minimize the power consumption. The subthreshold region refers to the case where the gate voltage is below the gate threshold voltage.

The trigger voltages are set by M₁₀ and M₁₁ of the Schmitt trigger which will shift the output between high and low respectively. The operation of the Schmitt Trigger circuit can be explained as follows. When the input to the Schmitt trigger is 0 V (discharged capacitor), the two-stacked transistors (M₆ and M₇) will be on. Hence the output of Schmitt trigger (Vₒᵤₜ)=V_{DD}. When capacitor voltage rises to V_{TN} (the threshold voltage of the NMOS transistor), M₉ is on, but M₈ is still off since M₁₁ is on and the source voltage of M₈ is at V_{DD}. When the capacitor voltage rises further, the source voltage of M₈ lowers and ultimately both M₈ and M₉ are on, Vₒᵤₜ approaches ground rapidly and M₁₁ turns off When the capacitor voltage approaches V_{DD}, the two stacked n-MOSFET (M₈ and M₉) will be on and hence Vₒᵤₜ=0V. Similarly, when the capacitor falls to |V_{TP}| (the threshold voltage of the PMOS transistor), M₆ is on. But M₇ is still off since M₁₀ is on and source voltage of M₇ is at ground. Thus, the source voltage of M₇ rises with decreasing capacitor voltage. When the source voltage of M₇ rises to |V_{TP}|, M₇ turns on. At this point, both M₆ and M₇ are on, Vₒᵤₜ approaches V_{DD} rapidly and M₁₀ turns off.

The voltage Vₜ₁ can be expressed as follows

$${V}_{t 1} = \frac{{V}_{D D} + {V}_{T N} \sqrt{\frac{{k}_{9}}{{k}_{11}}}}{1 + \sqrt{\frac{{k}_{9}}{{k}_{11}}}} \qquad ( 2 )$$

with kᵢ=0.5μₙ Cₒₓ(W/L) and where μₙ is the charge-carrier effective mobility, W is the gate width, L is the gate length and Cₒₓ is the gate oxide capacitance per unit area. Similarly, it can be shown that Vₜ₂ is given by

$${V}_{t 2} = \frac{( {V}_{D D} - \vert {V}_{T P} \vert ) \sqrt{\frac{{k}_{6}}{{k}_{10}}}}{1 + \sqrt{\frac{{k}_{6}}{{k}_{10}}}} \qquad ( 3 )$$

The charging control block comprises PMOS transistors M₁, M₁₂ and M₁₃, which control the charging current to charge the capacitor. The width per unit length, W/L, for these transistors plays an important role in controlling the amount of current. M₁₂ and M₁₃ act as a current divider as W/L of M₁₃ is chosen to be greater than M₁₂, thus M₁₃ draws the larger ratio of current to ground while a small portion of current remains to charge the capacitor, C₁.

Similarly, the discharging block comprises NMOS transistors M₁₄, M₁₅ and M₁₆. The discharging M₁₄ and M₁₅ act as a voltage divider to bias the gate of M₁₆, which will control the amount of current discharging the capacitor.

As the charging block is comprised by PMOS transistors, their gates are connected to the feedback path which will turn them on when the output is zero. Similarly, the discharging block contains NMOS transistors which conduct only when the output logic is high. In this way, controlled charging and discharging is carried out. The charging and discharging time of the oscillator of the timer can be changed by varying the sizes of the charging and discharging path switching transistors. In a non-limiting example, the maximum half period using a 100 pF capacitor is around 44 seconds. For applications which require a greater time period, a capacitor can be added in parallel with 100 pF capacitor to increase the time period of the oscillator.

The drain current in a MOSFET is basically controlled by the gate-source voltage, V_{gs}, as beneath the sub threshold region (weak-inversion) the potential remains constant throughout the channel and the movement of minority charged carriers determines the flow of current per lateral doping concentration gradient.

The current in MOSFET transistors can also be reduced by increasing the channel resistance which plays important role in reduction of current. Choosing W/L of the transistors to be small will result in a small current through the transistor. The transistor parameters of drain current and channel resistance are selected to reduce the current in order to minimize the power consumption of the oscillator. The W/L parameters for the transistors are provided in Table 1.

TABLE 1
Sizes of the Transistors for Proposed Timer

| Transistors | W/L |
|---|---|
| M₁, M₂, M₃, M₄, M₅, M₁₀, | 320 n/150 n |
| M₁₁, M₁₂, M₁₄, M₁₆ | |
| M₆, M₇, M₈, M₉, | 1 u/1 u |
| M₁₃ | 5.63 n/150 n |
| M₁₆ | 3.5 u/1.5 u |

A first embodiment of the pulse width modulated sub-Hertz timer is described with respect to FIG. 1A, FIG. 1B and FIG. 2.

The pulse width modulated sub-Hertz timer 100 includes a Schmitt trigger 120 having a first input 170 and a first output 172, an inverter block 130 connected at its input to the first output, the inverter block having a second output 174; a charging control block 140 connected to the second output, the charging control block having a third output 177; a discharging control block 150 connected to the second output; the discharging control block having a fourth output 179. A capacitor, C₁, has a positive contact 170 coupled to the third and fourth outputs, and has a negative contact connected to ground. The first input of the Schmitt trigger is coupled to the positive contact of the capacitor at 170, the capacitor providing voltage to the first input.

The Schmitt trigger output 172 is a voltage output which switches polarity when the voltage at the first input is greater than a first threshold, Vₜ₁, or when the voltage at the first input is less than a second threshold Vₜ₂, wherein the first threshold is greater than the second threshold.

The timer 100 further comprises a plurality of PMOS transistors and a plurality of NMOS transistors, each transistor having a control gate, a drain, and a source as shown in FIG. 1B.

The Schmitt trigger 120 comprises a first PMOS transistor M6 in cascade with a second PMOS transistor M7, a first NMOS transistor M8 in cascade with a second NMOS transistor M9. The source of the first PMOS transistor M6 is connected to a voltage supply, V_{dd}, and the source of the second NMOS transistor M9 is connected to ground; the drain of the second PMOS transistor M7 is connected to the drain of the first NMOS transistor M8, the connection forming the first output 172. The control gates of the first and second PMOS transistors and the first and second NMOS transistors are connected together and form the first input 170 of the Schmitt trigger.

A third PMOS transistor M10 having its source connected to the drain of the first PMOS transistor M6, its drain connected to ground and its control gate connected to the first output 172; and a third NMOS transistor M11 having its source connected to the drain of the second NMOS transistor M9, its drain connected to the supply voltage, V_{dd}, and its control gate connected to the first output 172 provide the threshold voltages Vₜ₁ and Vₜ₂ for switching the polarity of the first output.

The first threshold Vₜ₁ can be adjusted by changing the width per unit length of the third PMOS transistor M10; and the second threshold Vₜ₂ can be adjusted by changing the width per unit length of the third NMOS transistor M11.

The sub-hertz timer has an ON time output and an OFF time output; wherein the frequency of the ON time output is less than one Hertz.

The charging control block 140 comprises a fourth PMOS transistor M1 in cascade with a fifth PMOS transistor M12, wherein the control gates of the fourth and fifth PMOS transistors are connected together and are further connected to the second output 174, the source of the fourth PMOS transistor M1 is connected to the supply voltage, V_{dd}, and the drain of the fifth PMOS transistor M12 is connected to the positive contact of the capacitor at 170. The charging control block 140 further comprises a sixth PMOS transistor M13, the source of the sixth PMOS transistor connected to the drain of the fourth PMOS transistor M1, the control gate of the sixth PMOS transistor connected to the second output 174, and the drain of the sixth PMOS transistor is connected to ground.

The discharging control block 150 of the timer 100 comprises a fourth NMOS transistor M14 in cascade with a fifth NMOS transistor M15, wherein the control gates of the fourth and fifth NMOS transistors are connected together and are further connected to the second output 174. The drain of the fourth NMOS transistor M14 is connected to the second output 174 and the source of the fifth NMOS transistor M15 is connected to ground. The discharging control block 150 further comprises a sixth NMOS transistor M16, the drain of the sixth NMOS transistor connected to the positive contact 170 of the capacitor C₁, the source is connected to ground, and the control gate is connected to the source of the fourth NMOS transistor M14.

The operation of the control blocks is as follows. The charging control block 140 charges the capacitor C₁ when the second output 174 at the inverter 130 is zero, and the discharging control block 150 discharges the capacitor when the output of the inverter is V_{dd}.

The charging time can adjusted by changing the width per unit length of the sixth PMOS transistor M13; and the discharging time is adjusted by changing the width per unit length of the fifth NMOS transistor M15.

The design parameters of the third PMOS transistor M10 and the third NMOS transistor M11 are chosen to determine Vₜ₁ and Vₜ₂ according to the equations:

$${V}_{t 1} = \frac{{V}_{D D} + {V}_{T N} \sqrt{\frac{{k}_{9}}{{k}_{11}}}}{1 + \sqrt{\frac{{k}_{9}}{{k}_{11}}}} \\ {V}_{t 2} = \frac{( {V}_{D D} - \vert {V}_{T P} \vert ) \sqrt{\frac{{k}_{6}}{{k}_{10}}}}{1 + \sqrt{\frac{{k}_{6}}{{k}_{10}}}}$$

where kᵢ=0.5μₙ Cₒₓ(W/L) and where μₙ is the charge-carrier effective mobility, W is the gate width, L is the gate length and Cₒₓ is the gate oxide capacitance per unit area.

Switching of the polarity of the first output 172 occurs at a frequency, f_{osc}, defined by the equation:

$${f}_{o s c} = \frac{2 {I}_{o n}}{C 1 ( Vth 1 - Vth 2 )} ,$$

where Iₒₙ is the current at the drain of fifth PMOS transistor M12 which charges the capacitor, C₁.

The inverter comprises a seventh PMOS transistor M2 in cascade with an eighth PMOS transistor M3, a seventh NMOS transistor M4 in cascade with an eighth NMOS transistor M5, wherein the drain of the eighth PMOS transistor M3 is connected to the drain of the seventh NMOS transistor M4, the connection between the drain of the eighth PMOS transistor M3 and the drain of the seventh NMOS transistor M4 defining the second output 174. The source of the seventh PMOS transistor M2 is connected to the positive supply voltage, V_{dd}, and the source of the eighth NMOS transistor M5 is connected to ground.

A second embodiment to a method for using a pulse width modulated sub-Hertz timer is shown with respect to FIG. 1A, 1B, 2.

The timer includes a plurality of PMOS transistors and a plurality of NMOS transistors, each transistor having a control gate, a source and a drain, as shown in FIG. 1B.

The method includes initially charging, by current generated by a voltage source, V_{dd}, a capacitor, C₁ to start the timer, then connecting a positive contact 170 of the capacitor to a first voltage input of a Schmitt trigger, the first input of the Schmitt trigger including a first PMOS transistor M6 in cascade with a second PMOS transistor M7, a first NMOS transistor M8 in cascade with a second NMOS transistor M9; connecting the drain of the second PMOS transistor M7 with the drain of the first NMOS transistor M8, the connection forming the first output 172. The method continues by connecting the control gates of the first M6 and second PMOS M7 transistors in series with the control gates of the first M8 and second M9 NMOS transistors, wherein the connection of the control gates forms the first input 170 to the Schmitt trigger. Threshold transistors are coupled by connecting the source of a third PMOS transistor M10 to the drain of the first PMOS transistor M6, connecting the drain of the third PMOS transistor to ground and connecting its control gate to the first output 172; connecting the source of a third NMOS transistor M11 to the drain of the second NMOS transistor M9, connecting the drain of the third NMOS transistor M11 to the supply voltage, V_{dd}, and connecting its control gate to the first output 172.

The method of using the timer includes generating a first output voltage 172 of the Schmitt trigger based on the voltage level of the first voltage input 170; switching polarity of the first output voltage based on the voltage level of the first input; inverting, by inverter 130, the first output voltage 172 to form a second output voltage 174 and providing the second output voltage 174 to the control gates of a charging control block 140 and a discharging control block 150. The capacitor C₁ is alternately charged by current from the charging control block 150 and discharged by grounding at the discharging control block, based on the polarity of the second voltage output 174.

The Schmitt trigger output 172 switches polarity when the voltage at the input is greater than a first threshold, Vₜ₁, or when the voltage at the input is less than a second threshold Vₜ₂, where Vₜ₁ is greater than Vₜ₂. The frequency of switching the polarity by the Schmitt trigger is given by the equation:

$${f}_{o s c} = \frac{2 {I}_{o n}}{C 1 ( Vth 1 - Vth 2 )} ,$$

where Iₒₙ is the current which charges the capacitor, C₁; wherein the ON frequency of the timer is less than one Hertz.

The method for using further comprises adjusting the first threshold by changing the width per unit length of the third PMOS transistor M10; and adjusting the second threshold by changing the width per unit length of the third NMOS transistor M11; adjusting the charging time of the capacitor C₁ by changing the width per unit length of the sixth PMOS transistor M13; adjusting the discharging time by changing the width per unit length of the fifth NMOS transistor M15. Adjusting the first and second thresholds, the charging time and the discharging time changes the ON time and the OFF time of the timer, wherein the frequency of the ON time is adjusted to be less than one Hertz.

A third embodiment to a method for making a pulse width modulated sub-Hertz timer is described with respect to FIG. 1A, 1B, 2. The timer is constructed using a plurality of PMOS transistors and a plurality of NMOS transistors, each transistor having a control gate, a source and a drain as shown in FIG. 1B.

The third embodiment entails constructing a Schmitt trigger 120 having a first input 170 and a first output 172, constructing an inverter block 130 connected at its input to the first output 172, the inverter block having a second output 174; constructing a charging control block 140 connected to the second output 174, the charging control block having a third output 177; constructing a discharging control block 150 connected to the second output 174; the discharging control block having a fourth output 179; coupling a positive contact 170 of a capacitor, C₁, to the third 177 and fourth outputs 179, and connecting a negative contact of the capacitor to ground. The first input of the Schmitt trigger to the positive contact 170 of the capacitor.

Constructing a Schmitt trigger 120 comprises connecting a first PMOS transistor M6 in cascade with a second PMOS transistor M7, connecting a first NMOS transistor M8 in cascade with a second NMOS transistor M9, connecting the source of the first PMOS transistor M6 to a voltage supply, V_{dd}; connecting the source of the second NMOS transistor M9 to ground; connecting together the control gates of the first M6 and second M7 PMOS transistors and the first M8 and second NMOS M9 transistors to form the first input 170 of the Schmitt trigger 120; and connecting the drain of the second PMOS transistor M7 to the drain of the first NMOS transistor M8, the connection forming a first output of a Schmitt trigger. The ability of the Schmitt trigger to switch the polarity of the first output is determined by a third PMOS transistor M10 and a third NMOS transistor M11. These transistors are inserted in the Schmitt trigger by connecting the source of the third PMOS transistor M10 to the drain of the first PMOS transistor M6, its drain to ground and its control gate to the first output 172; and connecting the source of the third NMOS transistor M11 to the drain of the second NMOS transistor M9, its drain connected to the supply voltage, V_{dd}, and its control gate to the first output 172. The method for making includes choosing design parameters of the third PMOS transistor M10 to set a first trigger threshold, Vₜ₁, of the Schmitt trigger and choosing design parameters of the third NMOS transistor M11 to set a second trigger threshold, Vₜₕ₂, of the Schmitt trigger, wherein the first trigger threshold is greater than the second trigger threshold, wherein the design parameters of the third PMOS transistor and the third NMOS are chosen to determine Vₜ₁ and Vₜ₂ according to the equations:

$${V}_{t 1} = \frac{{V}_{D D} + {V}_{T N} \sqrt{\frac{{k}_{9}}{{k}_{11}}}}{1 + \sqrt{\frac{{k}_{9}}{{k}_{11}}}} \\ {V}_{t 2} = \frac{( {V}_{D D} - \vert {V}_{T P} \vert ) \sqrt{\frac{{k}_{6}}{{k}_{10}}}}{1 + \sqrt{\frac{{k}_{6}}{{k}_{10}}}}$$

where kᵢ=0.5μₙ Cₒₓ(W/L) and where μₙ is the charge-carrier effective mobility, W is the gate width, L is the gate length and Cₒₓ is the gate oxide capacitance per unit area.

The method for making continues by constructing a charging control block 140 by connecting a fourth PMOS transistor M1 in cascade with a fifth PMOS transistor M12, connecting the control gates of the fourth and fifth PMOS transistors together and to the second output 174; connecting the source of the fourth PMOS transistor to the supply voltage, V_{dd}, and connecting the drain of the fifth PMOS transistor to the positive contact of the capacitor; connecting the source of a sixth PMOS transistor M13 to the drain of the fourth PMOS transistor M1; and connecting the control gate of the sixth PMOS transistor M13 to the second output 174, and connecting the drain of the sixth PMOS M13 transistor to ground. The charging time may be adjusted by changing the width per unit length of the sixth PMOS transistor.

Constructing the discharging control block 150 comprises connecting a fourth NMOS transistor M14 in cascade with a fifth NMOS transistor M15, connecting the control gates of the fourth and fifth NMOS transistors together and to the second output; connecting the drain of the fourth NMOS transistor to the second output, V_{dd}; connecting the source of the fifth NMOS transistor to ground; and connecting the drain of a sixth NMOS transistor M16 to the positive contact of the capacitor, its source to ground, and its control gate to the source of the fourth NMOS transistor M14.

The discharging time may be adjusted by changing the width per unit length of the fifth NMOS transistor.

Constructing the inverter 130 comprises connecting a seventh PMOS transistor M2 in cascade with an eighth PMOS transistor M3; connecting a seventh NMOS transistor M4 in cascade with an eighth NMOS transistor M5, connecting the drain of the eighth PMOS transistor M3 to the drain of the seventh NMOS transistor M4, the connection between the drain of the eighth PMOS transistor and the drain of the seventh NMOS transistor defining the second output 174; connecting the source of the seventh PMOS transistor M2 to the positive supply voltage, V_{dd}, connecting the source of the eighth NMOS transistor M5 to ground.

A non-limiting example of post layout results and waveforms obtained using CMOS 150 nm technology in Cadence is described below.

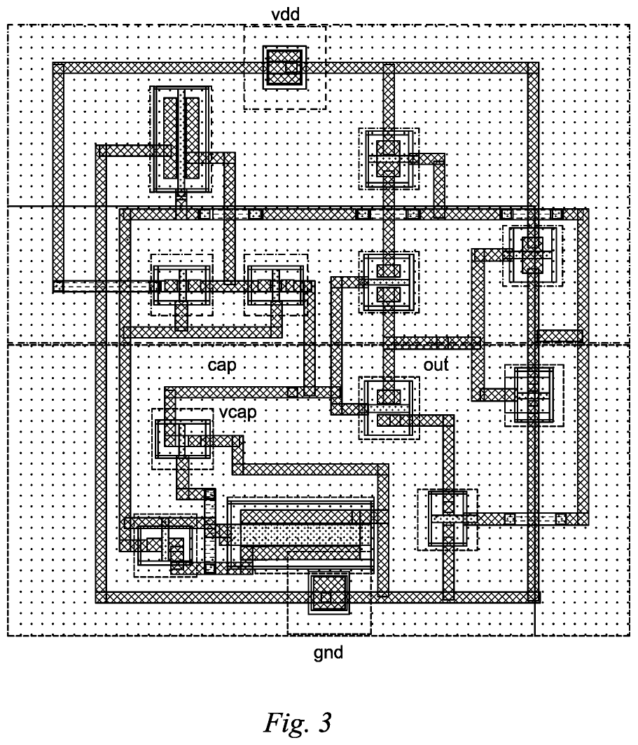

The circuit layout of the active area for the Schmitt trigger-based timer is shown in FIG. 3. The simulation was carried out in Cadence® with 0.15 um CMOS technology. The layout of proposed Schmitt trigger occupies an area of 223 μm² without the capacitor.

The circuit is connected to a 0.4V supply to ensure the subthreshold operation of circuit.

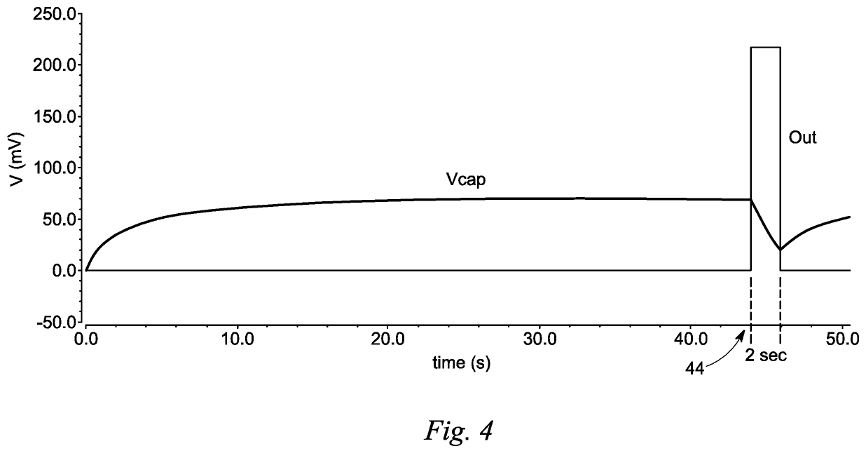

In a first non-limiting design example, an industrial monitoring system for gas sensing is shown. Typically, the timer is required to remain off for 44 seconds and only turns on for 2 seconds. Therefore, the Schmitt trigger sets the upper threshold voltage at 68.9 mv while the lower threshold is kept at 20.32 mv, which oscillates the capacitor voltage between these thresholds and maintains an output amplitude of 48.58 mV for the capacitor voltage. The output of the oscillator switches between 0V and 216.5 mV. The result is shown in FIG. 4.

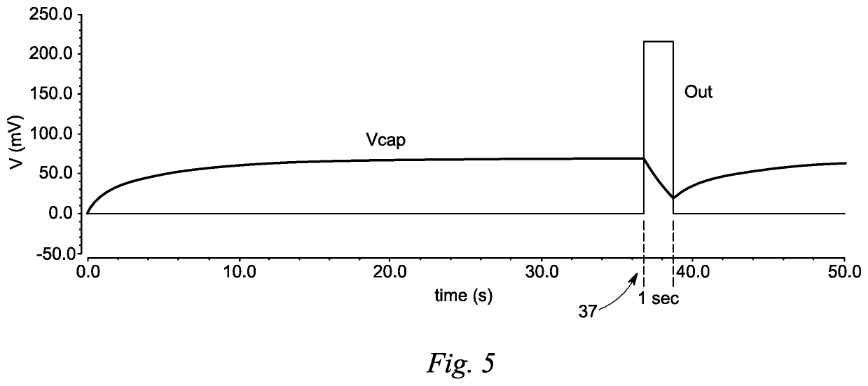

In a second non-limiting design sample, the timer is designed to be off for 37 seconds and on for 1 second. The threshold voltages for the Schmitt trigger can be changed by either adjusting the supply voltage or changing the size for the Schmitt trigger transistors. Therefore, the width, W, for M15 was changed from 2μ to 3.5μ in order to change the threshold voltages for the Schmitt trigger. To change the off time for the timer, the size of M13 is varied while for change of on time, the size of M₁₅ in varied. The change of size of each transistor will have the effect on both on and off timing but affects one more than the other depending on the W/L. Changing the size of M₁₃ will change OFF time with a small change in ON time. Similarly, a size change in M₁₅ will effect ON time with a small effect on OFF time. The corresponding results are shown in FIG. 5.

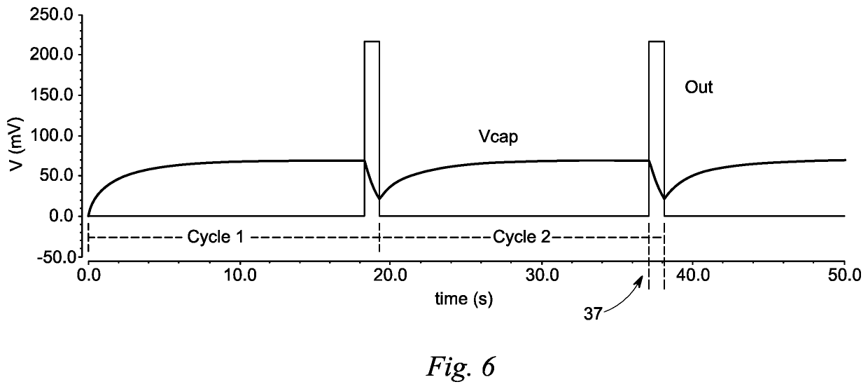

In a third non-limiting example, the frequency of oscillation is designed to be 0.05 Hz while keeping the same ratio between the ON and OFF time. The capacitor is selected to be 52.6 pF while keeping the other parameters constant; this will change the frequency of the timer, yielding two cycles in 37 seconds, as shown in FIG. 6.

Power consumption of the circuit is 320 pW during ON time. The average power consumption in the first non-limiting example is 13.91 pW per period when the timer is OFF for 44 seconds and ON for 2 seconds. Comparison with state of art timers (low frequency category) is summarized in Table 2. Table 2 includes the main characteristics of the timer of the present disclosure and the timers of Lin et al., 2007 (13), Lin et al. (2009)(14), Jeong et al. (15), and Lee et al. (16). (See Lin, Y-S.; Sylvester, D.; Blaauw, D: A 150 pW Program-and-Hold Timer for Ultra-Low Power Sensor Platforms. In: IEEE International Solid-State Circuits Conference, Digest of Technical Papers, pp. 326-328 (2009); Jeong, S.; et al.: A 5.8 nW CMOS Wake-Up Timer for Ultra-Low-Power Wireless Applications. IEEE Journal of Solid-State Circuits. 50(8), pp. 1754-1763 (2015); and Lee, Y.; et al.: A Sub-nW Multi-Stage Temperature Compensated Timer for Ultra-Low-Power Sensor Nodes. IEEE Journal of Solid-State Circuits. 48(10), pp. 2511-2521 (2013), each incorporated herein by reference in their entirety).

TABLE 2
Comparison with Literature

| | This Work | | [13] | | [14] | | [15] | | [16] | |
|---|---|---|---|---|---|---|---|---|---|---|
| Technology | 150 | nm | 0.13 | μm | 0.13 | μm | 0.18 | μm | 0.13 | μm |
| Technique | Subthreshold/ | | Single stage- | | Program | | Relaxation | | Multi stage- | |
| | current steering | | gate leakage | | and Hold | | Oscillator | | gate leakage | |
| Area | 223 | μm² | 480 | μm² | 0.02 | mm² | 0.24 | mm² | 0.015 | mm² |
| Frequency | 0.0217 | Hz | 0.08 | Hz | 11 | Hz | 11 | Hz | 0.37 | Hz |
| Supply Voltage | 400 | mV | 400 | mV | 600 | mV | 1.2 | V | 1.25 | V |
| Power | 13.91 | pW | 120 | pW | 150 | pW | 5.8 | nW | 660 | pW |
| Consumption | | | | | | | | | | |

| | | | | | |
|---|---|---|---|---|---|
| Need for | No | Yes | No | No | Yes |
| special Process | | | | | |
| PWM Feature | Yes | No | No | No | Yes |

The results shown in Table 2 verify that the pulse width modulated sub-Hertz timer of the present disclosure performs favorably as compared with state of the art timers, having the lowest comparative power consumption, the lowest operating frequency, the smallest active area, and includes pulse width modulation. Further, the timer of the present disclosure is compatible with standard CMOS technologies.

The sub-hertz timer uses standard CMOS transistors working in subthreshold. The circuit operates on a low voltage of 0.4V and makes use of pulse width modulation to set the desired ON-OFF time for specific applications. The pulse width modulation is achieved by choosing the W/L of charging and discharging blocks for the capacitor. The minimum oscillation frequency achieved (with a 100 pF capacitor) is 0.0217 Hz. The average power consumption for this oscillator is 13.91 pW in one period.

The proposed timer is highly adaptable to different applications and can be used to monitor the environment indoors and outdoors. Also, a modified version of the proposed timer was designed for high frequency operation in order to utilize it in the implementation of new digital delta-sigma modulator and PWM based DC—DC converters such as those of Cho et al., Salem et al., and Kim et al. (See Cho. Y-K.; Kim. M-D.; Kim, C.Y.: A Low Switching-Noise and High Efficiency Buck Converter Using a Continuous-Time Reconfigurable Delta-Sigma Modulator. IEEE Transactions on Power Electronics. PP(89), pp. 1-1 (2018); Salem, L; Warchall, J.; Mercier, P.: A Successive Approximation Recursive Digital Low-Dropout Voltage Regulator with PD Compensation and Sub-LSB Duty Control. IEEE Journal of Solid-State Circuits. 53(1), pp. 35-49 (2018); and [19] Kim, S.-Y.; et al.: Design of a High Efficiency DC-DC Buck Converter with Two-Step Digital PWM and Low Power Self-Tracking Zero Current Detector for IoT Applications. IEEE Transactions on Power Electronics. 33(2), pp. 1428-1439 (2018), each incorporated herein by reference in their entirety).

Obviously, numerous modifications and variations of the present invention are possible in light of the above teachings. It is therefore to be understood that within the scope of the appended claims, the invention may be practiced otherwise than as specifically described herein.

1. A pulse width modulated sub-Hertz timer, comprising:
a Schmitt trigger having a first input and a first output,
an inverter block connected at its input to the first output, the inverter block having a second output;
a charging control block connected to the second output, the charging control block having a third output;
a discharging control block connected to the second output; the discharging control block having a fourth output;
a capacitor having a positive contact coupled to the third and fourth outputs, and having a negative contact connected to a ground;
wherein the first input of the Schmitt trigger is coupled to the positive contact of the capacitor, the capacitor providing a voltage to the first input;
wherein the Schmitt trigger output switches polarity when the voltage at the first input is greater than a first threshold or when the voltage at the first input is less than a second threshold, wherein the first threshold is greater than the second threshold;
wherein the pulse width modulated sub-Hertz timer comprises a plurality of PMOS transistors and a plurality of NMOS transistors, each transistor having a control gate, a drain, and a source;
wherein the Schmitt trigger comprises a first PMOS transistor of the plurality of PMOS transistors in cascade with a second PMOS transistor of the plurality of PMOS transistors, a first NMOS transistor of the plurality of NMOS transistors in cascade with a second NMOS transistor of the plurality of NMOS transistors,
wherein the source of the first PMOS transistor is connected to a voltage supply;
wherein the source of the second NMOS transistor is connected to the ground;
wherein the drain of the second PMOS transistor is connected to the drain of the first NMOS transistor, wherein the first output is located at the connection of the drain of the second PMOS transistor and the drain of the first NMOS transistor,
wherein the control gates of the first and second PMOS transistors and the first and second NMOS transistors are connected together and form the first input of the Schmitt trigger;
a third PMOS transistor of the plurality of PMOS transistors having its source connected to the drain of the first PMOS transistor, its drain connected to the ground and its control gate connected to the first output;
a third NMOS transistor of the plurality of NMOS transistors having its source connected to the drain of the second NMOS transistor, its drain connected to the supply voltage, and its control gate connected to the first output;
wherein the charging control block comprises a fourth PMOS transistor of the plurality of PMOS transistors in cascade with a fifth PMOS transistor of the plurality of PMOS transistors, wherein the control gates of the fourth and fifth PMOS transistors are connected together and are further connected to the second output;
wherein the source of the fourth PMOS transistor is connected to the supply voltage and the drain of the fifth PMOS transistor is connected to the positive contact of the capacitor; and
the charging control block further comprises a sixth PMOS transistor of the plurality of PMOS transistors, wherein the source of the sixth PMOS transistor is connected to the drain of the fourth PMOS transistor, the control gate of the sixth PMOS transistor is connected to the second output, and the drain of the sixth PMOS transistor is connected to the ground.

2-3. (canceled)

4. The pulse width modulated sub-Hertz timer of claim 1,
wherein the first threshold is adjusted by changing the width per unit length of the third PMOS transistor; and
wherein the second threshold is adjusted by changing the width per unit length of the third NMOS transistor.

5. The pulse width modulated sub-Hertz timer of claim 1, wherein the sub-hertz timer has an ON time output and an OFF time output;
wherein the frequency of the ON time output is less than one Hertz.

6. (canceled)

7. The pulse width modulated sub-Hertz timer of claim 1,
wherein the discharging control block comprises a fourth NMOS transistor of the plurality of NMOS transistors in cascade with a fifth NMOS transistor of the plurality of NMOS transistors, wherein the control gates of the fourth and fifth NMOS transistors are connected together and are further connected to the second output;
wherein the drain of the fourth NMOS transistor is connected to the second output and the source of the fifth NMOS transistor is connected to the ground;
the discharging control block further comprising a sixth NMOS transistor of the plurality of NMOS transistors, wherein the drain of the sixth NMOS transistor is connected to the positive contact of the capacitor, the source is connected to the ground, and the control gate is connected to the source of the fourth NMOS transistor.

8. The pulse width modulated sub-Hertz timer of claim 7, wherein the charging control block charges the capacitor when the output of the inverter is zero, and wherein the discharging control block discharges the capacitor when the output of the inverter equals the supply voltage.

9. The pulse width modulated sub-Hertz timer of claim 8,
wherein the charging time is adjusted by changing the width per unit length of the sixth PMOS transistor; and
wherein the discharging time is adjusted by changing the width per unit length of the fifth NMOS transistor.

10. (canceled)

11. The pulse width modulated sub-Hertz timer of claim 1, wherein the polarity switches at a frequency, f_{osc}, defined by the equation:
f_{osc}=2Ion/C1(Vth1−Vth2),
where C₁ is the capacitor, Vₜₕ₁ is the first threshold, Vₜₕ₂ is the second threshold, and Iₒₙ is the current at the drain of fifth PMOS transistor which charges the capacitor.

12. The pulse width modulated sub-Hertz timer of claim 7, wherein the inverter comprises a seventh PMOS transistor of the plurality of PMOS transistors, in cascade with an eighth PMOS transistor of the plurality of PMOS transistors, a seventh NMOS transistor of the plurality of NMOS transistors, in cascade with an eighth NMOS transistor of the plurality of NMOS transistors, wherein the drain of the eighth PMOS transistor is connected to the drain of the seventh NMOS transistor, the connection between the drain of the eighth PMOS transistor and the drain of the seventh NMOS transistor defining the second output;
wherein the source of the seventh PMOS transistor is connected to the supply voltage,
wherein the source of the eighth NMOS transistor is connected to the ground.

13.-20. (canceled)
